(19) United States
(12) Patent Application Publication
(10) Pub. No.: US 2025/0054745 A1
(43) Pub. Date: Feb. 13, 2025

(54) METHOD FOR FABRICATING A DONOR SUBSTRATE

(71) Applicant: Soitec, BERNIN (FR)

(72) Inventors: Sebastien Thibert, BERNIN (FR); Clement Gaumer, BERNIN (FR); Cédric Charles-Alfred, BERNIN (FR)

(21) Appl. No.: 18/722,862

(22) PCT Filed: Dec. 23, 2022
(86) PCT No.: PCT/EP2022/087749

§ 371 Date: Jun. 21, 2024

(30) Foreign Application Priority Data
Dec. 23, 2021 (FR) FR2114469

(51) Int. Cl. H01L 21/02; H01L 21/20; H01L 21/762; H10N 30/073; H10N 30/853

(52) U.S. Cl. CPC H01L 21/02002; H01L 21/2007; H01L 21/76254; H10N 30/073; H10N 30/853

(57) ABSTRACT

A method for fabricating a donor substrate comprises the steps of A: providing a handle substrate, B: providing a target substrate, C: attaching the target substrate to the handle substrate, and D: rectifying, in particular, by grinding, the target substrate attached to the handle substrate, so as to form the donor substrate, the method being characterized in that a waiting time period of a predetermined duration is observed between step C and step D.

### CROSS-REFERENCE TO RELATED APPLICATIONS

This application is a national phase entry under 35 U.S.C. § 371 of International Patent Application PCT/EP2022/087749, filed Dec. 23, 2022, designating the United States of America and published as International Patent Publication WO 2023/118574 A1 on Jun. 29, 2023, which claims the benefit under Article 8 of the Patent Cooperation Treaty of French Patent Application Serial No. FR2114469, filed Dec. 23, 2021.

### TECHNICAL FIELD

The present disclosure concerns a process for fabricating a donor substrate. Embodiments of the present disclosure find applications notably in the field of the fabrication of multi-layer substrates, such as piezo-on-insulator (POI) or silicon-on-insulator (SOI) substrates.

### BACKGROUND

It is known in the art to fabricate a donor substrate, also called donor virtual substrate (DVS), which is adapted for the transfer of a layer from the donor substrate to a carrier substrate. A DVS typically comprises at least one handle substrate, in particular, made of a semiconductor material such as silicon or sapphire, and a target substrate, a layer of which is intended to be transferred. A DVS is notably used in the context of the fabrication of a multi-layer substrate by a method of the SMARTCUT® type.

The implementation of a DVS for layer transfer has the main advantage of mitigating parasitic mechanical forces, which may be induced by a thermal expansion differential between a carrier substrate and a layer deposited on the carrier substrate. Thus, by adapting the thermal expansion coefficient of the donor substrate to that of the carrier substrate, it is possible to minimize the deformation during thermal treatments.

An additional advantage of the implementation of a DVS lies in the fabrication ergonomics, each donor substrate being able to be reused a number of times to provide, in each production cycle, a new layer to a new carrier substrate using a process of the SMARTCUT® type. This is referred to as a “refresh” of the DVS.

Thus, FR 18 52573 A1 discloses a first process for fabricating a donor substrate having good mechanical strength by polymerization of a photo-polymerizable adhesive layer. This process makes it possible to avoid resorting to high-temperature fabricating steps, which may be expensive and may lead to curvatures of the substrates.

In order to increase the production yield of multi-layer substrates such as POIs or SOIs, it is conceivable to reduce the quality defects that may occur during and at the end of the fabricating processes. In particular, material defects may be observed in the produced multi-layer substrates, such as cracks or crack initiators, notably at the edge of the substrates. These defects may result from the DVSs and be transferred to or occur on other substrates produced by the transfer of a layer from the donor substrate to a carrier substrate, for example, during a SMARTCUT® step. Thus, the occurrence of quality defects leads in some instances to production scrap.

Taking account of the foregoing, an object of the present disclosure is to provide a donor substrate fabrication process, which increases the production quality of the donor substrates, and leads to reduction in the occurrence of defects, in particular, the occurrence of defects observed on the final multi-layer substrates.

### BRIEF SUMMARY

In this regard, the present disclosure relates to a process for fabricating a donor substrate, comprising the steps of A: providing a handle substrate, B: providing a target substrate, C: attaching the target substrate to the handle substrate, comprising bonding by way of an adhesive layer, the adhesive layer being a layer of a photo-polymerizable material, in particular, a layer of a photo-polymerizable liquid with a thickness of 3 μm to 8 μm, and D: rectifying, in particular, by grinding, the target substrate attached to the handle substrate, so as to form the donor substrate. The process is characterized in that a waiting period of a predetermined duration is observed between step C and step D.

According to an unexpected discovery, the implementation of a waiting period of a predetermined duration between steps C and D may lead to a significant reduction in the quantity of cracks observed in the multi-layer substrates produced from donor substrates fabricated by the process that forms the subject matter of the present disclosure. Specifically, the waiting period may allow the constituent elements of the non-rectified donor substrate to rest and improve in robustness. In particular, the stabilizing effect of the adhesive layer of the photo-polymerizable material for the attachment in step C may be amplified. Thus, the non-rectified donor substrate may be rendered more resistant to the mechanical stresses incurred during the following rectification, and during a subsequent layer transfer step. Consequently, the proportion of multi-layer substrates, fabricated from donor substrates, having a risk of cracking may be reduced and the overall quality of the production of multi-layer substrates may be increased. For example, by reducing the quantity of cracks at the edge of the substrate, the surface area or the radius of a usable substrate may be increased.

According to one aspect of the present disclosure, the target substrate is a piezoelectric substrate, in particular, a piezoelectric substrate comprising a material selected from among quartz, lithium tantalate, lithium niobate, aluminum nitride, zinc oxide, gallium orthophosphate, barium titanate, langasite, langanite, gallium nitride, lead zirconate titanate or langatate.

Thus, the DVS obtained by the process may be used to fabricate POI substrates. Since piezoelectric substrates are particularly valuable due to their high price and diverse applicability, a reduction in the production scrap by the inventive process may be all the more advantageous.

According to one aspect of the present disclosure, the handle substrate comprises a material selected from among silicon, sapphire, aluminum nitride, silicon carbide or gallium arsenide.

By selecting one of these materials, the thermal expansion coefficient of the handle substrate may be advantageously adapted to a subsequent use of the DVS for the fabrication of a multi-layer substrate.

According to one aspect of the present disclosure, the predetermined duration is at least 24 h, preferentially at least 48 h, and preferably at least 105 h.

By selecting the predetermined duration in this way, it is possible to obtain particularly great gains in quality of substrates produced. For example, it is possible to obtain rates of cracking of 20% or less, 10% or less or 5% or less respectively on the multi-layer substrates obtained from donor substrates fabricated by the process according to this aspect of the present disclosure.

According to one aspect of the present disclosure, the predetermined duration is less than 300 h, preferentially less than 200 h, and preferably less than 150 h.

By limiting the duration of the waiting period in this way, it is possible to maintain a good balance between gain in production quality and reduction in production throughput. According to one aspect of the present disclosure, the predetermined duration is determined as a function of the material of the adhesive layer.

The waiting period may thus be adapted to the adhesion and relaxation properties specific to each adhesive layer material. In particular, this may make it possible to precisely adapt the waiting period required to obtain a gain in quality of substrates produced.

According to one aspect of the present disclosure, the predetermined duration is selected, on the basis of a statistical study formulating a rate of cracking observed on multi-layer substrates obtained from the donor substrates fabricated by this process according to the duration of the observed waiting period, such that the duration corresponds to the duration required to obtain a rate of cracking of 20% or less, in particular, of 10% or less, or even more particularly of 5% or less. In particular, the statistical study may result from tests comprising at least 500 fabricated donor substrates, for example, in the form of wafers.

By basing the duration of the waiting period on such a statistical study, it is possible to adapt the process even more precisely to a desired quality objective of the donor substrate produced.

According to one aspect of the present disclosure, the waiting period is observed under ambient conditions. The costs and the footprint for environmental control equipment are thus avoided and the effect of the present disclosure can be obtained.

Another object of the present disclosure concerns a process for transferring a layer from a donor substrate to a carrier substrate, comprising the steps of A: providing a donor substrate obtained by the implementation of an aspect of the process described above, B: forming a weakened zone in the target substrate so as to delimit the layer of the target substrate to be transferred, C: providing a carrier substrate, notably comprising a material corresponding to a material of the handle substrate, D: attaching the donor substrate to the carrier substrate, and E: fracturing and separating the donor substrate along the weakened zone.

The implementation of this process may make it possible to obtain a multi-layer substrate with a reduced occurrence of material defects, as elaborated above: by implementing a waiting period of a predetermined duration, the quality of the obtained donor substrates may be increased. Consequently, the layer of the target substrate that is transferred to the carrier substrate is also of a higher quality.

The combination of the process for fabricating a donor substrate with this process for transferring a layer from a donor substrate is particularly advantageous because the fractured donor substrate, that is to say the remainder of the donor substrate remaining after step E, can be reused. Thus, for example, in the context of a “refresh” of a process of the SMARTCUT® type, it is possible for the same residual donor substrate to be prepared, in a subsequent production cycle, for transferring another layer of the target substrate to another carrier substrate.

### BRIEF DESCRIPTION OF THE DRAWINGS

The objects, features and advantages of the present disclosure as outlined above will be more exhaustively understood and appreciated upon studying the more detailed description below concerning the present disclosure, and upon studying the appended drawings.

FIG. 1 diagrammatically represents the successive steps of a process for fabricating a donor substrate according to one embodiment of the present disclosure.

FIG. 2 diagrammatically represents the successive steps of a process for transferring a layer according to one embodiment of the present disclosure.

To make the figures clearer, the illustrated elements are not necessarily shown to scale, neither relative to one another, nor in terms of their relative Cartesian dimensions.

FIG. 3 shows a graph derived from test results effected in the context of the optimization of the fabricating process.

### DETAILED DESCRIPTION

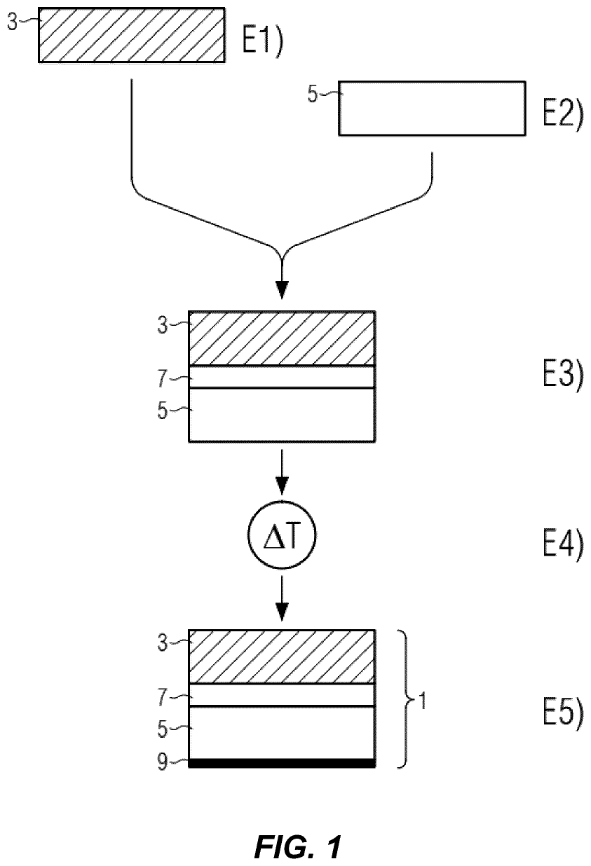

One embodiment of a process for fabricating a donor substrate 1 according to the present disclosure is described with reference to FIG. 1. FIG. 1 diagrammatically illustrates the successive steps of the fabrication of the donor substrate 1.

The process comprises a step E1 of providing a handle substrate 3. The handle substrate 3 may comprise a material selected from among silicon (Si), sapphire (Al₂O₃), aluminum nitride (AlN), silicon carbide (SiC), gallium arsenide (GaAs), quartz (SiO₂), or another glass.

The process comprises a step E2 of providing a target substrate 5. The target substrate 5 is a substrate that is intended to be subsequently transferred, at least in part, to a carrier substrate.

According to one embodiment of the process, the target substrate 5 may be a piezoelectric substrate. For example, the target substrate 5 may comprise a material selected from among LTO (La₂Ti₂O₇), quartz (SiO₂), lithium tantalate (LiTaO₃), lithium niobate (LiNbO₃), aluminum nitride (AlN), zinc oxide (ZnO), gallium orthophosphate (GaPO₄), barium titanate (BaTiO₃), langasite (La₃Ga₅SiO₁₄), langanite (La₃Ga_{5.5}Nb_{0.5}O₁₄), gallium nitride (GaN), lead zirconate titanate (PZT) or langatate (La₃Ga_{5.5}Ta_{0.5}O₁₄). These materials are particularly suitable for bulk acoustic wave (BAW) or surface acoustic wave (SAW) applications, such as a SAW sensor or a BAW filter on the basis of POI.

According to another embodiment, the target substrate 5 may be a substrate comprising a semiconductor material such as silicon (Si), sapphire (Al₂O₃), aluminum nitride (AlN), silicon carbide (SiC), gallium arsenide (GaAs), quartz (SiO₂), or another glass.

In a step E3, the target substrate 5 is attached to the handle substrate 3. In this embodiment, the attachment in step E3 is carried out by bonding, notably by bonding by way of an adhesive layer 7. An adhesive layer of a photo-polymerizable material is preferably employed. Such a material can be polymerized when it is irradiated with a light flux. By way of example, in this step an adhesive layer 7, with a thickness of 3 μm to 8 μm, of the product sold under the reference “NOA 61” by NORLAND PRODUCTS may be formed, and then subjected to UV radiation through the exposed surface of the target substrate 5 attached to the handle substrate 3.

According to the present disclosure, and contrary to the processes known in the art for fabrication of a donor substrate, the process continues with a step E4 during which the fabricating process is interrupted for a waiting period of a predetermined duration. The waiting period is at least 24 h, and preferably 105 h.

The waiting period is observed under ambient conditions. That is to say that, while waiting, the target substrate 5 attached to the handle substrate 3 is kept at an ambient temperature, notably a temperature between 20° C. and 26° C., and at an ambient pressure, notably a pressure between 950 hPa and 1030 hPa.

Finally, the target substrate 5 attached to the handle substrate 3 is subjected to a rectification step E5. Rectification is understood to mean a surface treatment aiming to reduce the roughness of the exposed surface 9 of the target substrate 5 attached to the handle substrate 3. Rectification is preferably effected by grinding or by chemical mechanical polishing (CMP).

In an example, the rectification may comprise a succession of multiple steps of grinding and/or CMP. As variant, the rectification may comprise one or several steps of dry etching, for example, reactive ion etching, or RIE according to the English term “reactive ion etching.”

This fabricating process results in a donor substrate according to embodiments of the present disclosure. The use of a handle substrate 3 is advantageous, for example, for fabricating a SOI or POI substrate, since, contrary to conventional methods such as epitaxial growth, it makes it possible to avoid deformations induced by high temperatures during thermal treatments.

The bonding by adhesive layer 7 in step E3 ensures satisfactory mechanical cohesion of the two bonded substrates. By using a photo-polymerizable material, the attachment can be effected without resorting to bonding under high temperature, for example, at more than 200° C.

The rectification in step E5 makes it possible to obtain a surface of uniform flatness, which is sufficiently smooth for a subsequent transfer of a layer to a carrier substrate, for example, using a process of the SMARTCUT® type.

Unexpectedly, it was discovered that fewer defects are observed when the donor substrates 1 have been subjected to the waiting period between the attachment step E3 and the rectification step E5. The effect is particularly advantageous in comparison with multi-layer substrates, for example, POI or SOI substrates, obtained with donor substrates 1 fabricated without observing a waiting period. Specifically, the waiting period allows the constituent elements of the non-rectified donor substrate 1, that is to say of the target substrate 5 attached to the handle substrate 3, to improve in robustness, before being subjected to the rectification, and notably before being subjected to a subsequent layer transfer step during the fabrication of a multi-layer substrate, for example, of the SOI or POI type, by SMARTCUT®. Thus, the non-rectified donor substrate is rendered more resistant to the mechanical stresses incurred during the rectification step or during a subsequent layer transfer. Consequently, the number of fabricated donor substrates 1 that are liable to lead to defects, and notably to result in cracks, at the end of the transfer of a layer of the target substrate, is reduced and the overall quality of the production is increased.

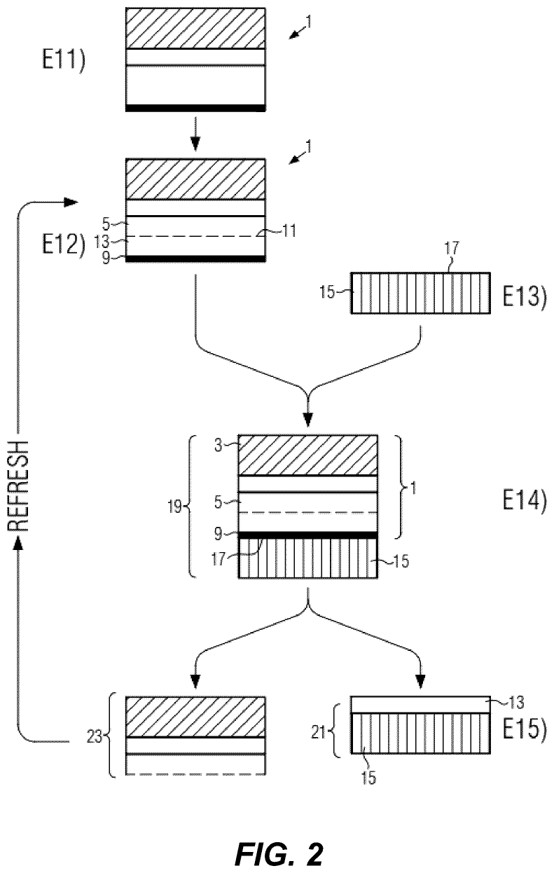

A process for transferring a layer from a donor substrate to a carrier substrate according to one embodiment of the present disclosure is described with reference to FIG. 2. The process described concerns a donor substrate 1 obtained by the process described in FIG. 1.

The process for transferring a layer starts with a step E11 of providing the donor substrate 1 resulting from step E4 of the fabricating process according to the embodiment of the present disclosure in FIG. 1.

Then, a weakened zone 11 is formed in the target substrate 5 of the donor substrate 1 in a step E12. The zone 11 is formed so as to delimit a layer 13 of the target substrate 5 to be transferred. The layer 13 is delimited in the target substrate 5 by the weakened zone 11 and by the rectified surface 9. The weakened zone 11 is preferably formed by implantation of ions, for example, of hydrogen ions or of a rare gas, such as helium. The dose of ions, the distribution of the dose of ions, and the implantation energy of the ions may vary, and determine the properties of the weakened zone 11 formed. The depth of the weakened zone 11 in the target substrate 5 determines the thickness of the layer 13 to be transferred.

A carrier substrate 15 is provided in a step E13. The carrier substrate 15 may preferably comprise a material selected from among silicon (Si), sapphire (Al₂O₃), aluminum nitride (AlN), silicon carbide (SiC), gallium arsenide (GaAs), quartz (SiO₂), or another glass. The carrier substrate has a main surface 17.

Preferably, the material of the handle substrate 3 of the donor substrate 1 has been selected so as to have a thermal expansion coefficient value that is equivalent or similar to the thermal expansion coefficient value of the carrier substrate 15, to which the layer 13 is intended to be transferred. A similar coefficient value typically corresponds to a value of between +10% and −10% of the reference value.

Thus, in order to obtain a suitable thermal expansion coefficient value, the carrier substrate 15 and the handle substrate 3 are preferably made of the same material.

In step E14, the donor substrate 1 is attached to the carrier substrate 15. The donor substrate 1 is attached by attaching the rectified surface 9 along the main surface 17 of the carrier substrate 15, forming a complex 19.

The attachment may be effected, for example, by bonding by way of a dielectric layer deposited on at least one of the two surfaces 9, 17 to be bonded. The dielectric layer may be, for example, a layer of glass deposited by centrifugation on the target substrate 5 according to the spin-on glass (SOG) method. The attachment may be reinforced by subjecting the surface to be bonded, on which the dielectric layer has not been deposited, to a treatment designed to subsequently allow hydrophilic molecular bonding with the surface on which the dielectric layer has been deposited. The attachment may also be reinforced by a densifying thermal annealing operation, for example, at a temperature of around 250° C. In this case, the parasitic mechanical forces induced by a thermal expansion differential between the carrier substrate 15 and the target substrate 5 are at least partially mitigated by the attachment of the target substrate 5 to the handle substrate 3, on the side opposite to the carrier substrate 15. Thus, the thermal expansion coefficients of the substrates 3 and 15 and of the target substrate 5 are similar.

Then, in step E15, the complex 19 of the donor substrate 1 comprising the weakened target substrate 5, which is attached to the carrier substrate 15, is fractured along the weakened zone 11 and separated into two parts: the final multi-layer substrate 21, such as a POI or SOI substrate, comprising the carrier substrate 15 to which the delimited layer 13 of the target substrate 5 has been transferred, and the remainder of the donor substrate after the fracturing step, denoted fractured donor substrate 23.

The fractured donor substrate 23 may be restored, or “refreshed,” in order to be re-subjected to step E12 for forming a weakened zone 11. Thus, steps E12, E13, E14 and E15 may be repeated a number of times on the basis of a single original donor substrate 1 provided, in order to produce several final multi-layer substrates 21, such as POI or SOI substrates. The number of “refreshes” possible with the donor substrate 1 is limited by the thickness of the target substrate 5 of the donor substrate 1, a layer 13 of which is removed in each iteration of a “refresh.” By contrast, material defects present in the target substrate 5 of the donor substrate 1 provided in step E11 remain therein, or even become more significant throughout the process described with reference to FIG. 2. In each cycle, these defects are transmitted in step E14 to the carrier substrate 15 via the transferred layer 13. An increase in overall quality of the donor substrate 1 provided in step E11 therefore cascades positively to all the products resulting from the process.

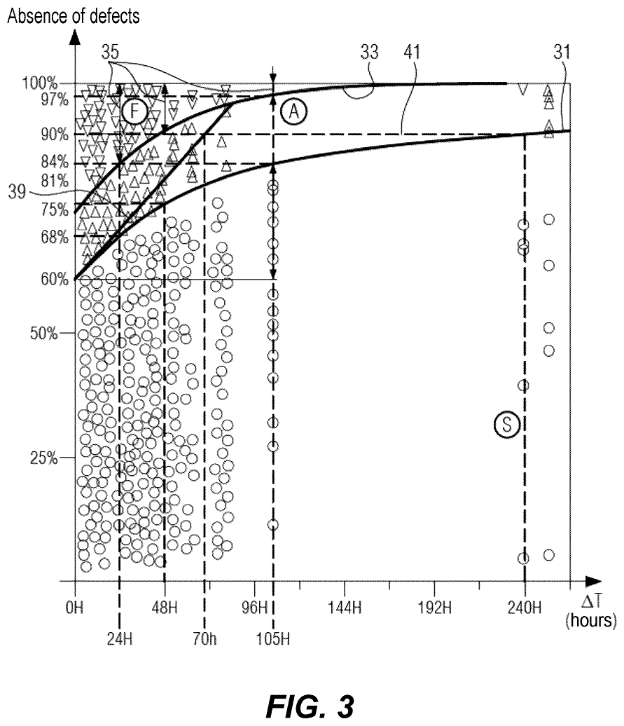

FIG. 3 reproduces, in graph form, the results from observing cracks on a sample of multi-layer substrates 21, for example, POI or SOI substrates, fabricated by the embodiment of the process of the present disclosure described above. The sample in FIG. 3 comprises 818 donor substrates 1 that have been fabricated by the process in FIG. 1 while observing varied waiting periods, up to a duration of 300 h. The substrates in the sample comprise a handle substrate 3 made of silicon (Si), a target substrate 5 made of LTO (La₂Ti₂O₇) and an adhesive layer 7 made of NOA 61.

FIG. 3 shows a graph concerning a sample of final multi-layer substrates 21 after step E15 of the process in FIG. 2 in a first production cycle. The donor substrate 1, from which the sample of substrates 21 has been produced, has therefore not yet been subjected to a “refresh” in the context of a SMARTCUT® process. Each point on the graph corresponds to a multi-layer substrate 21 of the sample for which the quality, that is to say the presence or absence of material defects, has been observed and recorded as a function of the waiting period observed in step E5 of the process for fabricating the donor substrate 1 in step E11.

Thus, the sample of tested multi-layer substrates is classified and quantified into three groups: without material defects (S), having a crack initiator (A), and having a crack (F). A crack initiator is a crack that does not pass all the way through the thickness of the substrate.

It is thus possible to determine, as a function of the waiting period observed during the fabrication of the donor substrate 1, the rate of absence of material defects T_a=S/(S+A+F) and the rate of absence of cracks T_b=(S+A)/(S+A+F). In FIG. 3, T_a is represented by reference 31 and T_b by reference 33. The curves 31 and 33 representing the rates T_a and T_b are obtained by non-linear regression of the statistical results of the observations.

By studying the curves 31 and 33 in FIG. 3, it is apparent that the longer the duration of the observed waiting period in step E4, the higher the rates T_a and T_b of fabricated multi-layer substrates without defects, respectively without cracks. Thus, the more the waiting period is extended, the more the quality of production obtained increases.

FIG. 3 makes it possible to identify that, generally, the rate of occurrence of material defects T_i (=1−T_a) may be reduced by selecting a predetermined duration of at least 24 h, preferentially at least 48 h, and preferably at least 105 h. These values make it possible to obtain particularly large gains in quality of substrates produced. Thus, from the graph in FIG. 3 it is possible to read rates T_a of absence of material defects of the order of 68%, 75% or 81% for these periods of 24 h, 48 h and 105 h, respectively. Furthermore, from the graph in FIG. 3 it is possible to read rates of cracking T_f (=1−T_b) of approximately 20%, 10% and 5% for these periods of 24 h, 48 h and 105 h, respectively, as identified by reference 35.

For example, this study makes it possible to read that, by observing a waiting period of 105 h during step E4, a gain in quality of 21% is acquired in relation to the level of material defects without observance of a waiting period.

At the same time, it is also apparent from curves 31 and 33 in FIG. 3 that the increase in the gain in quality of donor substrates fabricated decreases the longer the observed waiting period is. It is preferable not to interrupt the production lines and delay the production of a donor substrate for too long. Thus, it is preferable to limit the waiting time to at most 300 h, preferentially to at most 200 h, and preferably to at most 150 h. By limiting the duration of the waiting period in this way, it is possible to maintain a good balance between gain in quality and slowing of the production flow.

According to one variant of the present disclosure, the predetermined duration of step E4 may be selected on the basis of the curves 31 or 33 developed by the statistical study represented by FIG. 3. For example, a quality objective may be set, and the duration of the waiting period to be observed may be read from the curve 31 or 33 in question. For example, setting a quality objective for a rate of cracking of at most 3%, it suffices to identify the waiting period corresponding to the value T_b=97%, which corresponds in this instance to a period of 105 h. By thus basing the duration of the waiting period on the results of the study, the process is precisely adapted to the desired quality objective.

As an alternative, the predetermined waiting time in E4 may be determined by virtue of an analysis of the gradient of the curves 31 or 33. For example, the tangent of curve 31 at x=0 h, or the linear extrapolation of the rate T_a of absence of material defects between x=0 h and x=1 h, may be determined, as indicated by reference 39. The tangent 39 may be crossed with the asymptote 41 of the corresponding rate T_a so as to obtain a waiting period of 70 h for a T_b value of 90% or a T_a value of 78% for the multi-layer substrate 21.

According to one embodiment described above with reference to FIG. 1, the attachment of the target substrate to the handle substrate comprises a step of bonding by adhesive layer. In this case, it is appropriate to adapt the duration of the waiting period to the material of the adhesive layer, in particular, to the adhesion and relaxation properties specific to the material of the selected adhesive layer. For example, a comparative coefficient may be developed comparing the material of the selected adhesive layer with the mode of attachment selected in a reference case. The comparative coefficient may then be used to adapt the selected duration of the waiting period for the fabrication of the donor substrate in a more precise manner. This makes it possible to precisely adapt the waiting period required to obtain a maximum gain in quality of multi-layer substrates 21, in particular, of POI or SOI substrates, produced.

Thus, by providing a donor substrate according to the present disclosure, for example, a donor substrate 1 obtained by the process described with reference to FIG. 1, the process for transferring a layer may also be improved and provide multi-layer substrates of higher quality. For example, employing the SMARTCUT® method, it is possible to obtain commercial SOI and POI substrates with a higher yield by virtue of the reduction in material defects observed.

1. A method for fabricating a donor substrate, comprising:
providing a handle substrate;
providing a target substrate;
attaching the target substrate to the handle substrate, comprising bonding by way of an adhesive layer, the adhesive layer being a layer of a photo-polymerizable material;
rectifying the target substrate attached to the handle substrate, so as to form the donor substrate; and
wherein a waiting period of a predetermined duration is observed between the attaching of the target substrate to the handle substrate and the rectifying of the target substrate attached to the handle substrate.

2. The method of claim 1, wherein the target substrate is a piezoelectric substrate.

3. The method of claim 1, wherein the handle substrate comprises a material selected from among silicon, sapphire, aluminum nitride, silicon carbide or gallium arsenide.

4. The method of claim 1, wherein the predetermined duration is at least 24 h.

5. The method of claim 1, wherein the predetermined duration is less than 300 h.

6. The method of claim 1, wherein the predetermined duration is determined as a function of a material of the adhesive layer.

7. The method of claim 1, wherein the predetermined duration is selected on a basis of a statistical study.

8. The method of claim 1, wherein the waiting period is observed under ambient conditions.

9. The method of claim 1, wherein the attaching of the target substrate to the handle substrate comprises the irradiating the adhesive layer and polymerizing the adhesive layer.

10. A method for transferring a layer from a donor substrate to a carrier substrate, comprising:
providing a donor substrate obtained by implementation of the method according to claim 1;
forming a weakened zone in the target substrate so as to delimit the layer of the target substrate to be transferred;
providing a carrier substrate;
attaching the donor substrate to the carrier substrate; and
fracturing and separating the donor substrate along the weakened zone.

11. The method of claim 1, wherein the photo-polymerizable material comprises a layer of a photo-polymerizable liquid with a thickness of 3 μm to 8 μm.

12. The method of claim 1, wherein rectifying the target substrate comprises grinding the target substrate.

13. The method of claim 2, wherein the piezoelectric substrate comprises a material selected from among quartz, lithium tantalate, lithium niobate, aluminum nitride, zinc oxide, gallium orthophosphate, barium titanate, langasite, langanite, gallium nitride, lead zirconate titanate or langatate.

14. The method of claim 4, wherein the predetermined duration is at least 48 h.

15. The method of claim 14, wherein the predetermined duration is at least 105 h.

16. The method of claim 5, wherein the predetermined duration is less than 200 h.

17. The method of claim 16, wherein the predetermined duration is less than 150 h.

18. The method of claim 7, wherein the statistical study comprises:
testing at least 500 donor substrates; and
developing a rate of cracking observed on multi-layer substrates obtained from the donor substrates according to the duration of the observed waiting period; and
selecting the predetermined duration to correspond to the duration required to obtain a rate of cracking of 20% or less.

19. The method of claim 18, wherein selecting the predetermined duration to correspond to the duration required to obtain a rate of cracking of 20% or less comprises selecting the predetermined duration to correspond to the duration required to obtain a rate of cracking of 5% or less.

20. The method of claim 10, wherein providing the carrier substrate comprises providing a carrier substrate, comprising a material corresponding to a material of the handle substrate.
